(19) United States
(12) Patent Application Publication
(10) Pub. No.: US 2026/0182469 A1
(43) Pub. Date: Jun. 25, 2026

(54) PACKAGE INTERCONNECT INCLUDING A PILLAR HAVING A SIDEWALL SUITABLE FOR COUPLING SOLDER TO IMPROVE CONDUCTIVITY AND STRUCTURAL INTEGRITY

(71) Applicant: QUALCOMM Incorporated, San Diego, CA (US)

(72) Inventors: Heun Gun Shin, San Diego, CA (US); Jiaping Zhang, San Diego, CA (US)

(21) Appl. No.: 18/988,187

(22) Filed: Dec. 19, 2024

(51) Int. Cl. H01L 23/498; H01L 21/48; H01L 23/31; H01L 23/538; H01L 25/11

(52) U.S. Cl. CPC H10W 90/701; H10W 70/093; H10W 70/611; H10W 70/66; H10W 70/685; H10W 74/124; H10W 90/00

(57) ABSTRACT

Aspects disclosed include an integrated circuit (IC) package having a package interconnect including a pillar having a sidewall suitable for coupling solder to improve conductivity and structural integrity. The IC package includes a substrate comprising an outer metallization layer having a metal pad and a package mold layer adjacent to the outer metallization layer. The package mold layer has a circular aperture. The package interconnect extends from the metal pad and through the circular aperture. The pillar has two sidewalls. One side wall is directly adjacent to the package mold layer. The other sidewall has a diameter that is less than the diameter of the circular aperture which creates space for the other sidewall to couple to solder when the IC package is subsequently assembled with a printed circuit board (PCB).

### TECHNICAL FIELD

The field of the disclosure relates to integrated circuit (IC) packages, and more particularly to design and manufacturing of package interconnects.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The die(s) is electrically interfaced to metal interconnects (e.g., metal traces) exposed in a top layer of the package substrate. The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes a bottom, outer metallization layer that includes metal interconnects coupled to external metal interconnects (e.g., ball grid array (BGA) interconnects, land grid array (LGA)) to provide an external interface between the die(s) in the IC package. The external metal interconnects can also be coupled (e.g., soldered) to traces in a printed circuit board (PCB) to attach the package to the PCB and interface its die(s) with the circuitry of the PCB. The die(s) may be mounted to the top layer of the package substrate through die interconnects. Other die(s) may also be mounted, utilizing die interconnects, to the bottom, outer metallization layer that includes metal interconnects between BGA interconnects.

### SUMMARY

Aspects disclosed in the detailed description include a package interconnect including a pillar having a sidewall suitable for coupling solder to improve conductivity and structural integrity. The package interconnect is deployed in an integrated circuit (IC) package. The IC package includes a substrate comprising an outer metallization layer having a metal pad and a package mold layer adjacent to the outer metallization layer. The package mold layer has a circular aperture. The package interconnect extends from the metal pad and through the circular aperture. The pillar has two sidewalls. One side wall is directly adjacent to the package mold layer. The other sidewall has a diameter that is less than the diameter of the circular aperture which creates space for the other sidewall to couple to solder when the IC package is subsequently assembled with a printed circuit board (PCB). By deploying solder on the other sidewall, cracks in a solder joint coupled to the other sidewall caused by mechanical stress to the IC package are advantageously reduced and halted by the pillar. Additionally, the gap between the other sidewall and the circular aperture advantageously eliminates the need for deploying solder on both the package interconnect of the IC package and the PCB during the assembly process.

In this regard in one aspect, an electronic device is disclosed. The electronic device comprises an integrated circuit (IC) package. The IC package comprises a substrate extending in a horizontal direction, the substrate comprising an outer metallization layer having a metal pad. The IC package comprises a package mold layer extending in the horizontal direction and adjacent to the outer metallization layer, the package mold layer having a circular aperture, the circular aperture having an aperture sidewall and an aperture diameter and a package interconnect extending in a vertical direction. The package interconnect comprises a pillar extending in the vertical direction from the metal pad and through the circular aperture. The pillar comprises a first sidewall having a first diameter, the first diameter being less than the aperture diameter and a second sidewall directly adjacent to the package mold layer.

In another aspect, a method for fabricating an electronic device is disclosed. The method includes forming an integrated circuit (IC) package. Forming an IC package includes forming a substrate extending in a horizontal direction, the substrate comprising an outer metallization layer having a metal pad and forming a package mold layer extending in the horizontal direction and adjacent to the outer metallization layer. Forming a package mold layer comprises forming a circular aperture, the circular aperture having an aperture sidewall and an aperture diameter. Forming the IC package also includes forming a package interconnect extending in a vertical direction. Forming the package interconnect comprises forming a pillar extending in the vertical direction from the metal pad and through the circular aperture. Forming the pillar comprises forming a first sidewall having a first diameter, the first diameter being less than the aperture diameter and forming a second sidewall directly adjacent to the package mold layer.

### BRIEF DESCRIPTION OF THE DRAWINGS

FIG. 1A is a side view of an exemplary 3DIC package that includes a package interconnect including a pillar having a sidewall suitable for coupling solder to improve conductivity and structural integrity;

FIG. 1B is a close-up view of the package interconnect in FIG. 1A;

FIG. 1C is a view in the Z-axis direction of the bottom of the 3DIC package of FIG. 1A illustrating the bottom surfaces of package interconnects including the package interconnect in FIG. 1A;

FIG. 1D is a view of an electronic device including the 3DIC package in FIG. 1A assembled with a printed circuit board (PCB) illustrating the coupling of a solder joint to the sidewall of the pillar;

FIG. 2A is a side view of another exemplary 3DIC package that includes a package interconnect including a pillar having a sidewall suitable for coupling solder to improve conductivity and structural integrity;

FIG. 2B is a close-up view of the package interconnect in FIG. 2A;

FIG. 2C is a view in the Z-axis direction of the bottom of the 3DIC package of FIG. 2A illustrating the bottom surfaces of package interconnects including the package interconnect in FIG. 2A;

FIG. 2D is a view of an electronic device including the 3DIC package in FIG. 2A assembled with a PCB illustrating the coupling of a solder joint to the sidewall of the pillar;

FIG. 3A is a side view of another exemplary 3DIC package that includes a package interconnect including a pillar having a sidewall suitable for coupling solder to improve conductivity and structural integrity;

FIG. 3B is a close-up view of the package interconnect in FIG. 3A;

FIG. 3C is a view in the Z-axis direction of the bottom of the 3DIC package of FIG. 3A illustrating the bottom surfaces of package interconnects including the package interconnect in FIG. 3A;

FIG. 3D is a view of an electronic device including the 3DIC package in FIG. 3A assembled with a PCB illustrating the coupling of a solder joint to the sidewall of the pillar;

FIG. 4 is a flowchart illustrating an exemplary fabrication process of fabricating an electronic device including a package interconnect, wherein the package interconnect includes a pillar having a sidewall suitable for coupling solder to improve conductivity and structural integrity, the package interconnect, including, but not limited to, the package interconnects in FIGS. 1A-1D, 2A-2D, and 3A-3D;

FIGS. 5A-5F is a flowchart illustrating another exemplary fabrication process of fabricating a package interconnect, wherein the package interconnect includes a pillar having a sidewall suitable for coupling solder to improve conductivity and structural integrity, the package interconnect including, but not limited to, the package interconnects in FIGS. 1A-1D, 2A-2D, and 3A-3D;

FIGS. 6A-6I2 are exemplary fabrication stages during fabrication of the package interconnect according to the fabrication process in FIGS. 5A-5F;

FIG. 7 is a flowchart illustrating an exemplary assembly process of assembling an electronic device such as the electronic device having a 3DIC package coupled to a PCB in FIGS. 1D, 2D, and 3D and utilizing the 3DIC package fabricated according to the fabrication process in FIGS. 5A-5F, wherein the 3DIC package employs a package interconnect includes a pillar having a sidewall suitable for coupling solder to improve conductivity and structural integrity, the package interconnect including, but not limited to, the package interconnects in FIGS. 1A-1D, 2A-2D, and 3A-3D;

FIGS. 8A-8B are exemplary assembly stages during assembly of the electronic device according to the assembly process in FIG. 7;

FIG. 9 is a block diagram of an exemplary processor-based system that can include components such as an electronic device, wherein the electronic device includes a 3DIC package fabricated according to the fabrication process in FIGS. 4 and 5A-5F, wherein the 3DIC package employs a package interconnect including a pillar having a sidewall suitable for coupling solder to improve conductivity and structural integrity, the package interconnect including, but not limited to, the package interconnects in FIGS. 1A-1D, 2A-2D, and 3A-3D; and

FIG. 10 is a block diagram of an exemplary wireless communications device that includes radio-frequency (RF) components formed from one or more electronic devices, wherein the electronic device includes a 3DIC package fabricated according to the fabrication process in FIGS. 4 and 5A-5F, wherein the 3DIC package employs a package interconnect including a pillar having a sidewall suitable for coupling solder to improve conductivity and structural integrity, the package interconnect including, but not limited to, the package interconnects in FIGS. 1A-1D, 2A-2D, and 3A-3D.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include a package interconnect including a pillar having a sidewall suitable for coupling solder to improve conductivity and structural integrity. The package interconnect is deployed in an integrated circuit (IC) package. The IC package includes a substrate comprising an outer metallization layer having a metal pad and a package mold layer adjacent to the outer metallization layer. The package mold layer has a circular aperture. The package interconnect extends from the metal pad and through the circular aperture. The pillar has two sidewalls. One side wall is directly adjacent to the package mold layer. The other sidewall has a diameter that is less than the diameter of the circular aperture which creates space for the other sidewall to couple to solder when the IC package is subsequently assembled with a printed circuit board (PCB). By deploying solder on the other sidewall, cracks in a solder joint coupled to the other sidewall caused by mechanical stress to the IC package are advantageously reduced and halted by the pillar. Additionally, the gap between the other sidewall and the circular aperture advantageously eliminates the need for deploying solder on both the package interconnect of the IC package and the PCB during the assembly process.

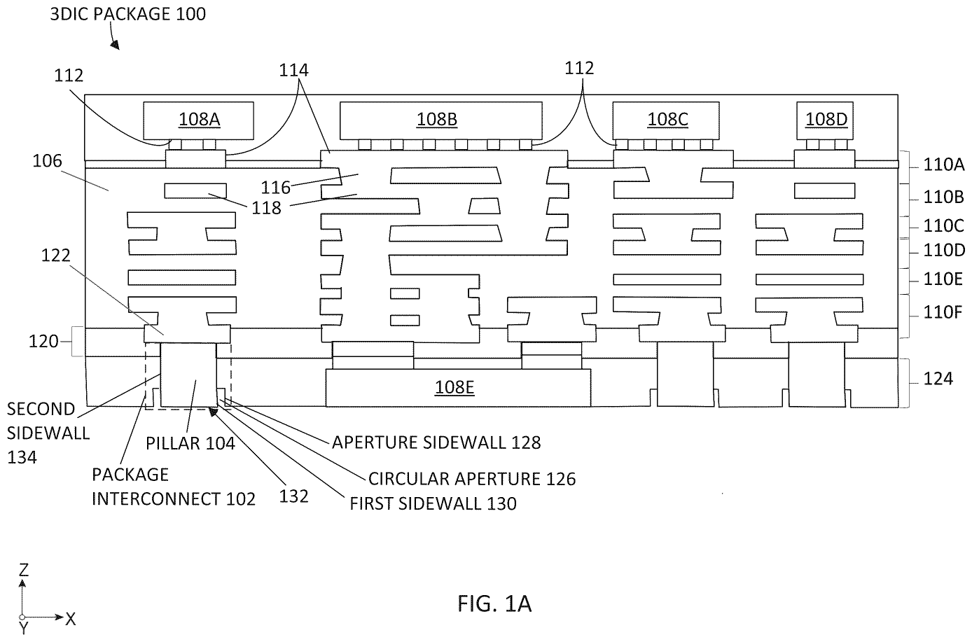

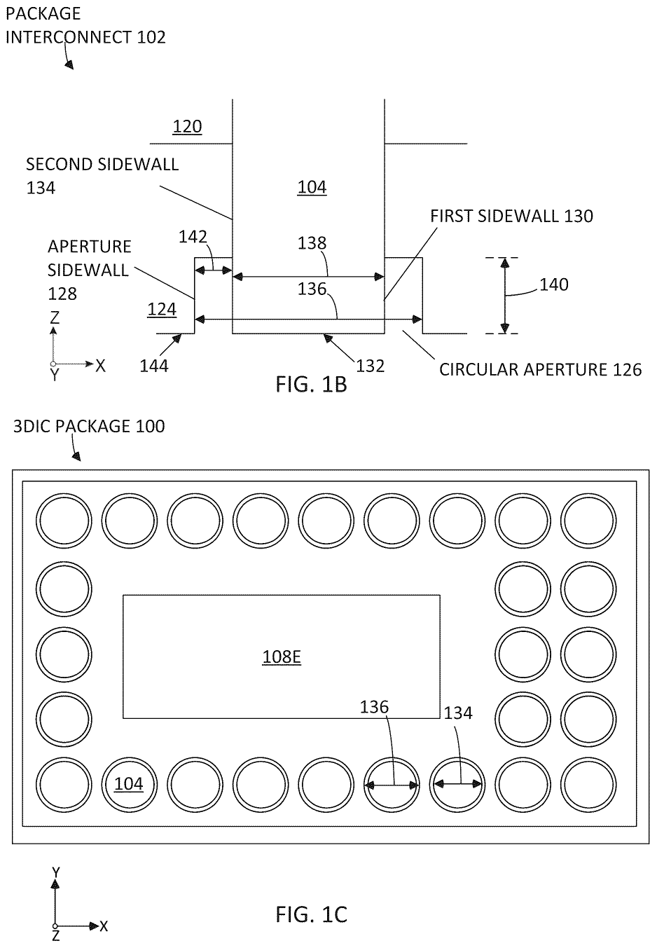

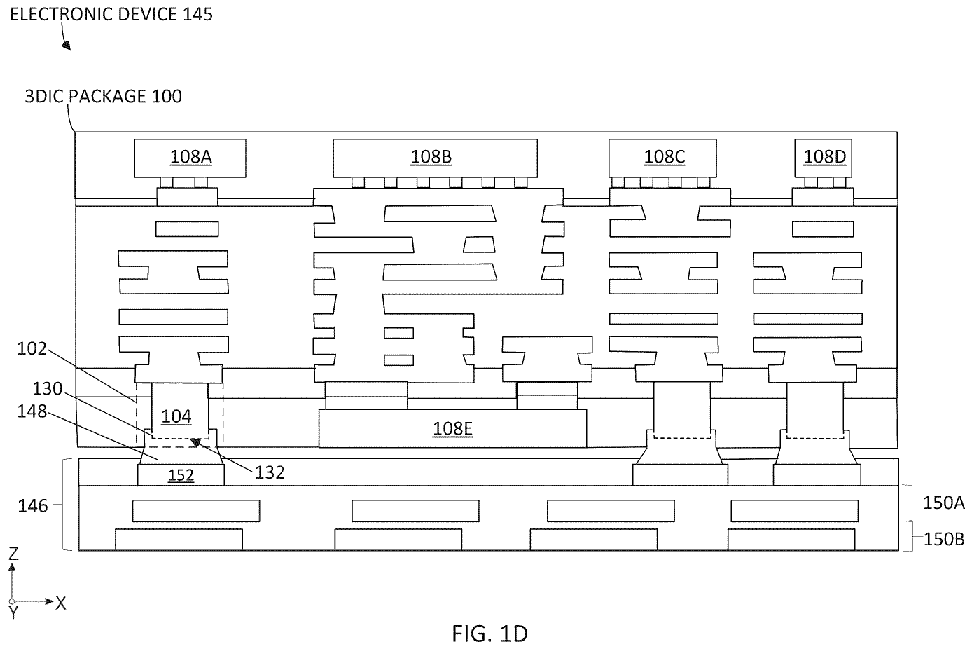

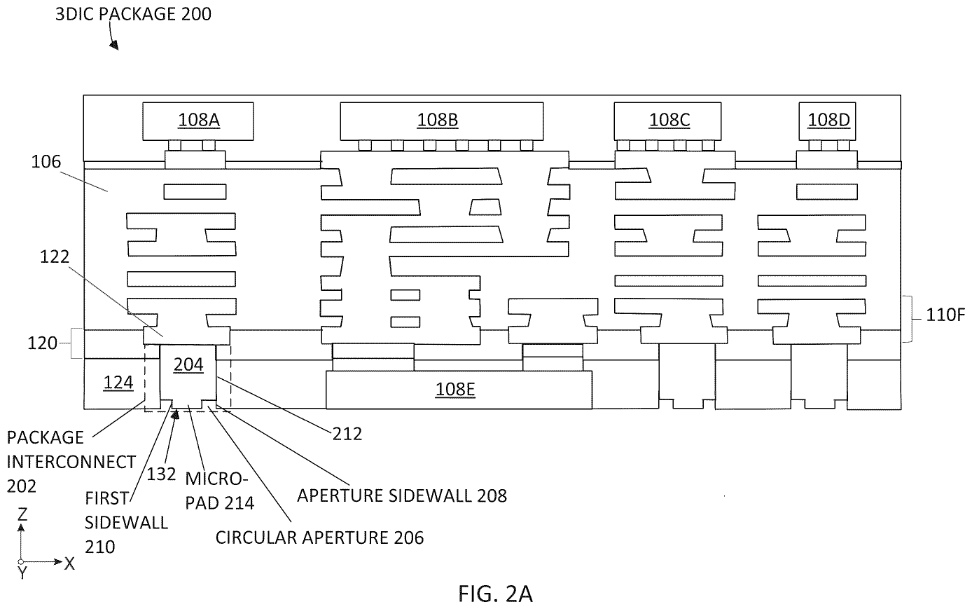

In this regard, FIG. 1A is a side view of an exemplary 3DIC package 100 that includes a package interconnect 102 including a pillar 104 having a sidewall suitable for coupling solder to improve conductivity and structural integrity. The IC package 100 includes a package substrate 106 extending in a horizontal direction (X-, Y-axes direction) and dies 108A-108D coupled to the top, in the vertical direction (Z-axis direction), of the package substrate 106 and die 108E coupled to the bottom of the package substrate 106. The package substrate 106 commonly routes signals and power between the dies 108A-108E and between the dies 108A-108E and a printed circuit board (not shown).

In this example, the package substrate 106 includes metallization layers 110(A)-110(F) including a first, upper metallization layer 110(A) and a bottom, outer metallization layer 110(F). The package substrate 106 provides interconnections between the upper metallization layer 110(A) and the second metallization layers 110(F) to provide signal routing between the dies 108(A)-108(E) and between the dies 108(A)-108(E) and a PCB. The first, upper metallization layer 110(A) provides an electrical interface for signal routing dies 108(A)-108(D). The dies 108(A)-108(D) are coupled to die interconnects 112 (e.g., raised metal bumps, pillars) that are electrically coupled to metal interconnects 114 in the first, upper metallization layer 110(A). The metal interconnects 114 in the first, upper metallization layer 110(A) are coupled to metal vias including metal via 116 in the package substrate 106, which are coupled to metal interconnects 118 in a second metallization layer 110(B) and continuing through metal vias and interconnects in metallization layers 110C-110(D) to the bottom, outer metallization layer 110(F). The package substrate 106 includes a solder mask layer 120. The outer metallization layer 110(F) includes metal pads including metal pad 122. The IC package 100 includes a package mold layer 124 extending in the horizontal direction and adjacent to the outer metallization layer 110(F), the package mold layer 124 has a circular aperture 126. The circular aperture 126 has an aperture sidewall 128 and an aperture diameter.

The package interconnect 102 extends in a vertical direction (Z-axis direction). The pillar 104 extends in the vertical direction (Z-axis direction) from the metal pad 122 and through the circular aperture 126. The pillar 104 comprises a first sidewall 130 that has a first diameter wherein the first diameter is less than the aperture diameter. This differential in diameters creates a gap between the aperture sidewall 128 and the first sidewall 130 which is suitable to be filled with solder when the IC package 100 is subsequently assembled with a PCB and advantageously increases the conductivity of the coupling between the pillar 104 and the PCB because the solder will adhere to the bottom surface 132 of the pillar 104 and the first sidewall 130. The pillar 104 comprises a second sidewall 134 which is directly adjacent to the package mold layer 124.

FIG. 1B is a close-up view of the package interconnect 102 in FIG. 1A. The aperture diameter 136 of the circular aperture 126 is around 215 micrometers (μm). The diameter 138 of the first sidewall of the pillar is around 170 μm. The height 140 of the circular aperture 126 in the vertical direction is around 60 μm. The gap 142 between the first sidewall 130 and the aperture sidewall 128 is around 45 μm. The ratio between the diameter 138 and the aperture diameter 136 is around 0.79. The package mold layer 124 has a bottom surface 144 which is co-planar with the bottom surface 132 of the pillar 104.

FIG. 1C is a view in the Z-axis direction of the bottom of the 3DIC package 100 of FIG. 1A illustrating the bottom surfaces of package interconnects including the package interconnect 102 in FIG. 1A.

FIG. 1D is a view of an electronic device 145 including the 3DIC package 100 in FIG. 1A assembled with a PCB 146 illustrating the coupling of a solder joint 148 to the first sidewall 130 of the pillar 104. The PCB 146 includes metallization layers 150A, 150B and metal pads including a metal pad 152 which couples to the metallization layers 150A, 150B to route signals between the dies 108A-108E and the PCB 146. The solder joint 148 is also coupled to the bottom surface 132 of the pillar 104 and surrounds the first sidewall 130 which improves conductivity between the package interconnect 102 and the PCB 146 by increasing the surface area in contact between the solder joint 148 and the pillar 104. With the solder joint 148 surrounding the first sidewall 130, the structural integrity of the solder joint 148 is improved because cracks in the solder are hindered and, if one develops, it is halted at the first sidewall 130.

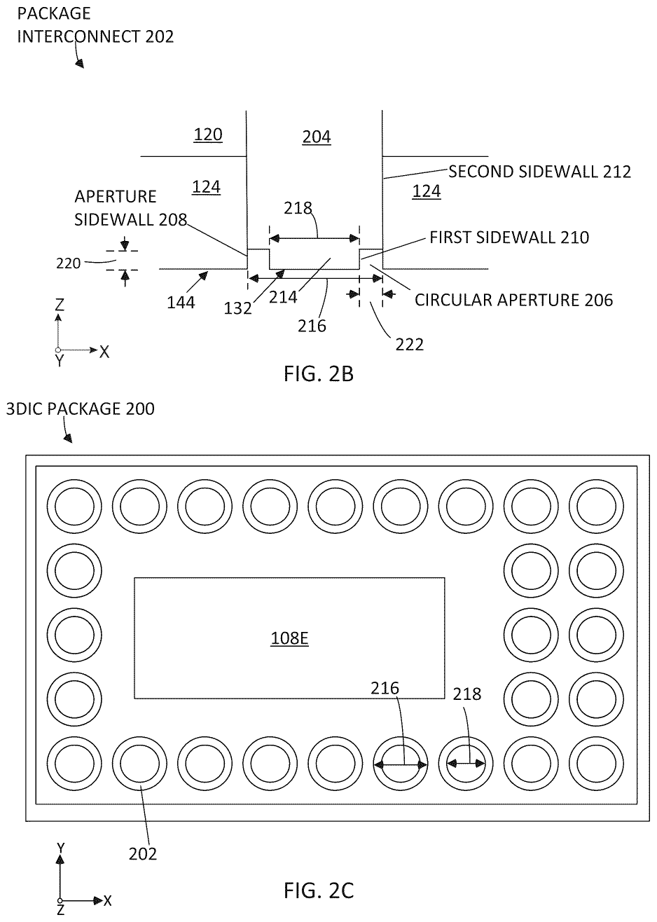

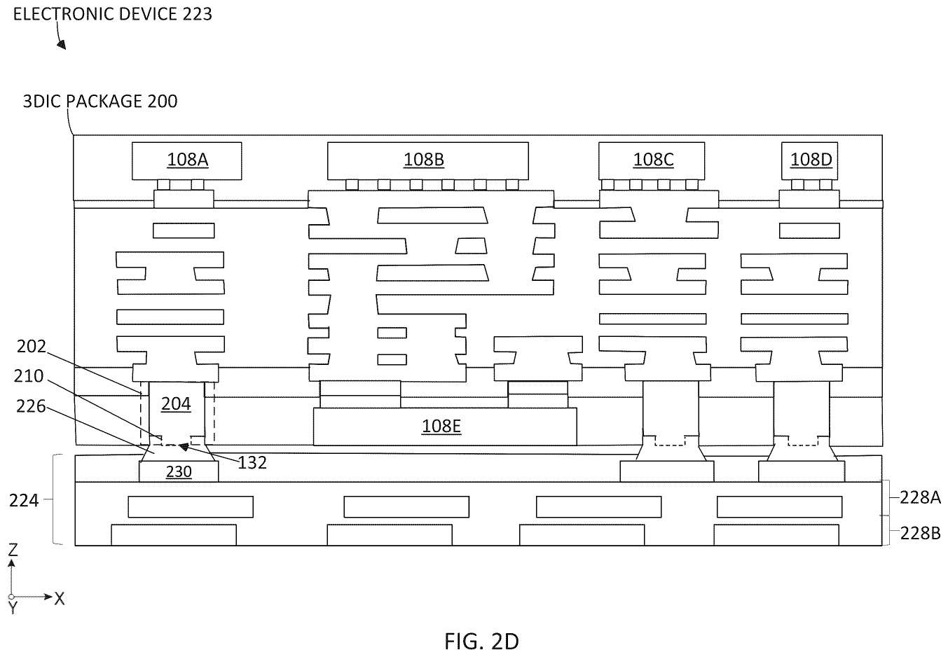

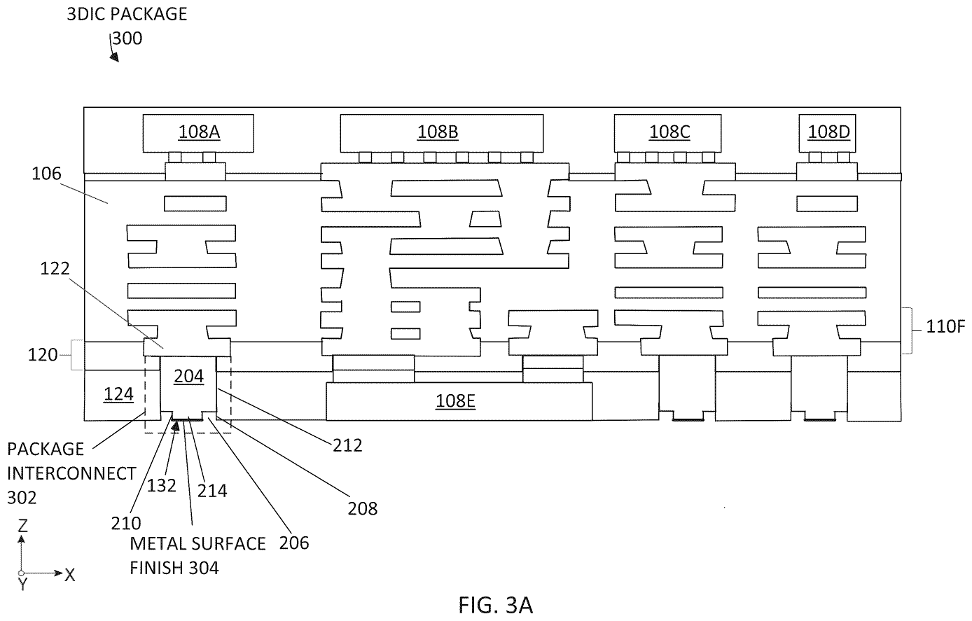

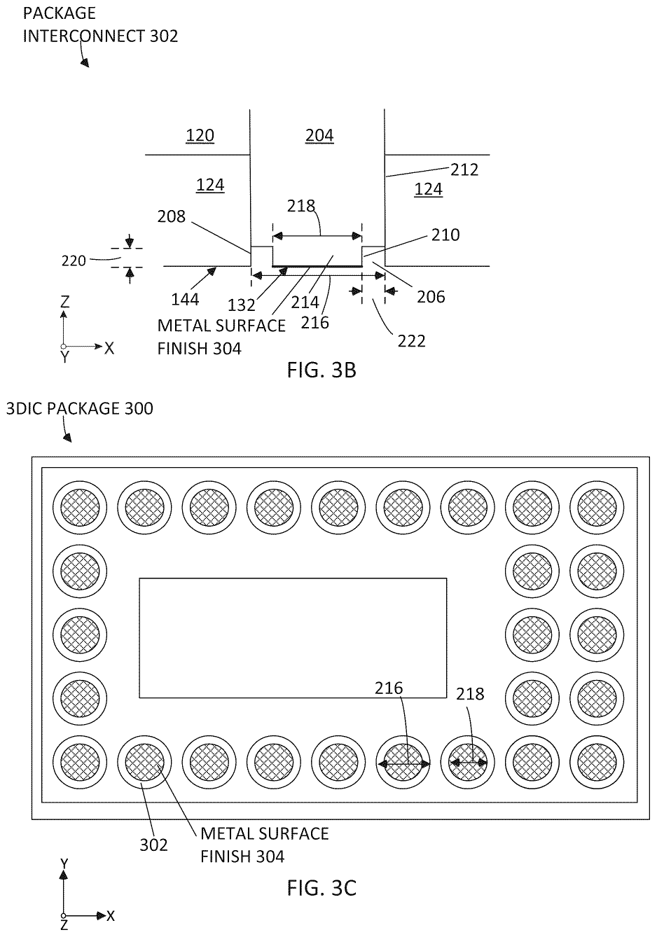

FIG. 2A is a side view of an exemplary 3DIC package 200 that includes a package interconnect 202 including a pillar 204 having a sidewall suitable for coupling solder to improve conductivity and structural integrity. Common elements between the IC package 200 in FIGS. 2A-2D and the IC package 100 in FIGS. 1A-1D are shown with common element numbers.

The package substrate 106 includes the solder mask layer 120. The outer metallization layer 110(F) includes metal pads including the metal pad 122. The IC package 200 includes the package mold layer 124 extending in the horizontal direction and adjacent to the outer metallization layer 110(F), the package mold layer 124 has a circular aperture 206. The circular aperture 206 has an aperture sidewall 208 and an aperture diameter.

The package interconnect 202 extends in a vertical direction (Z-axis direction). The pillar 204 extends in the vertical direction (Z-axis direction) from the metal pad 122 and through the solder mask layer 120 and the circular aperture 206. The pillar 204 comprises a first sidewall 210 that has a first diameter, wherein the first diameter is less than the aperture diameter. This differential in diameters creates a gap between the aperture sidewall 208 and the first sidewall 210 which is suitable to be filled with solder when the IC package 200 is subsequently assembled with a PCB and advantageously increases the conductivity of the coupling between the pillar 204 and the PCB because the solder will adhere to the bottom surface 132 of the pillar 204 and the first sidewall 210. The pillar 204 comprises a second sidewall 212 which is directly adjacent to the package mold layer 124.

The pillar 204 includes a micro-pad 214. The micro-pad 214 includes the first sidewall 210 which has the first diameter. The second sidewall 212 has a second diameter and is directly adjacent to the mold layer 124. The diameter of the micro-pad 214 is less than the diameter of the circular aperture 206. Also, the diameter of the micro-pad 214 is less than the diameter the pillar 204 measured at the second sidewall 212.

FIG. 2B is a close-up view of the package interconnect 202 in FIG. 2A. The aperture diameter 216 of the circular aperture 206 which is also the diameter of the second sidewall 212 is around 215 μm. The diameter 218 of the first sidewall 210 of the pillar 204 is around 170 μm. The height 220 of the circular aperture 206 in the vertical direction is around 60 μm. The gap 222 between the first sidewall 210 of the micro-pad 214 and the aperture sidewall 208 is around 45 μm. The ratio between the diameter 218 and the aperture diameter 216 (also diameter of second sidewall 212) is around 0.80. The package mold layer 124 has the bottom surface 144 which is co-planar with the bottom surface 132 of the pillar 204.

FIG. 2C is a view in the Z-axis direction of the bottom of the 3DIC package 200 of FIG. 2A illustrating the bottom surfaces of package interconnects including the package interconnect 202 in FIG. 2A.

FIG. 2D is a view of an electronic device 223 including the 3DIC package 200 in FIG. 2A assembled with a PCB 224 illustrating the coupling of a solder joint 226 to the first sidewall 210 of the pillar 204. The PCB 224 includes metallization layers 228A, 228B and metal pads including a metal pad 230 which couples to the metallization layers 228A, 228B to route signals between the dies 108A-108E and the PCB 224. The solder joint 226 is also coupled to the bottom surface 132 of the pillar 204 and surrounds the first sidewall 210 which improves conductivity between the package interconnect 202 and the PCB 224 by increasing the surface area in contact between the solder joint 226 and the pillar 204. With the solder joint 226 surrounding the first sidewall 210, the structural integrity of the solder joint 226 is improved because cracks in the solder are hindered and, if one develops, it is halted at the first sidewall 210.

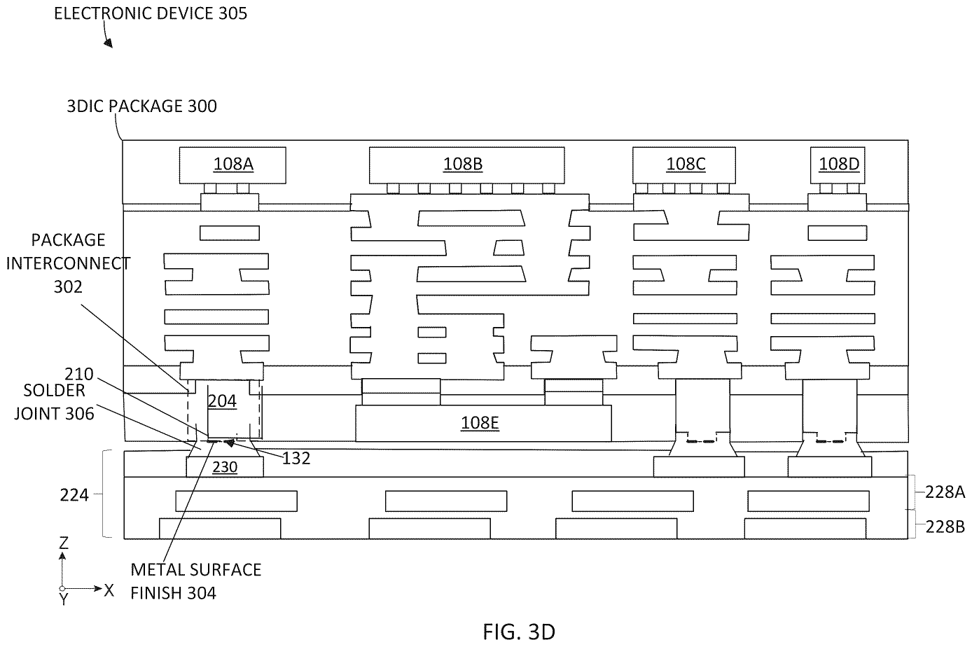

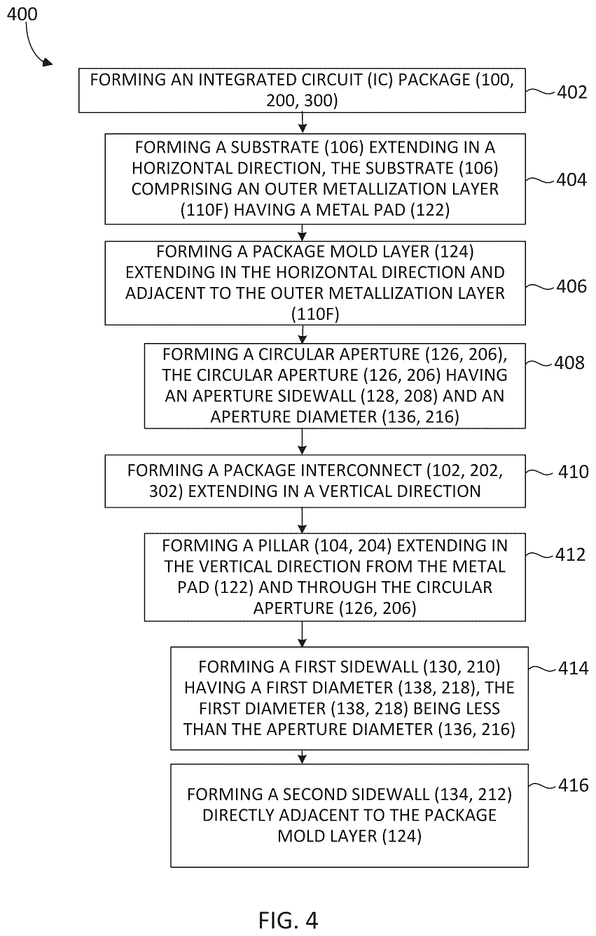

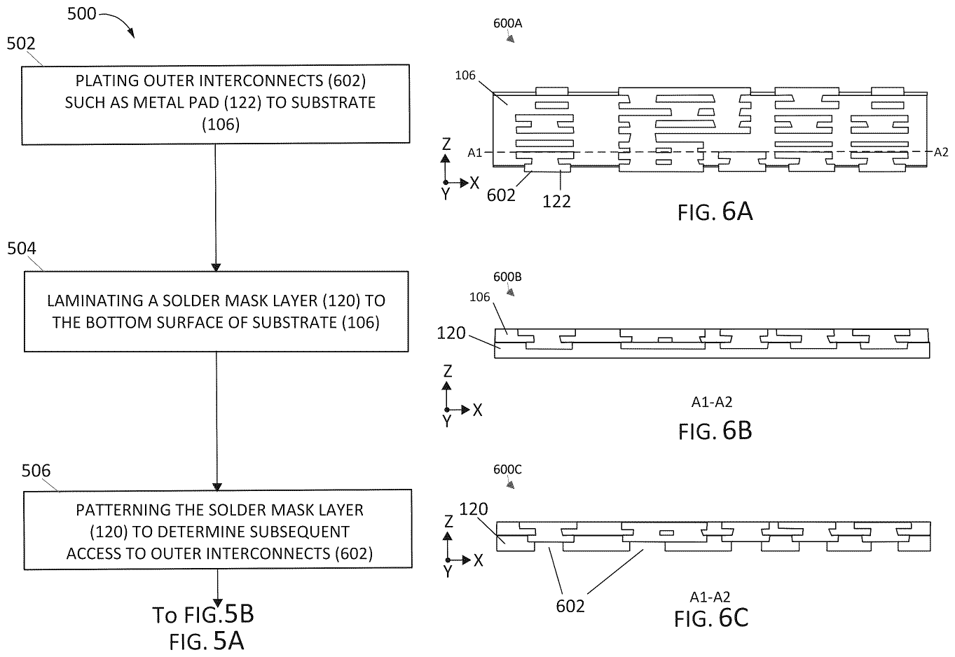

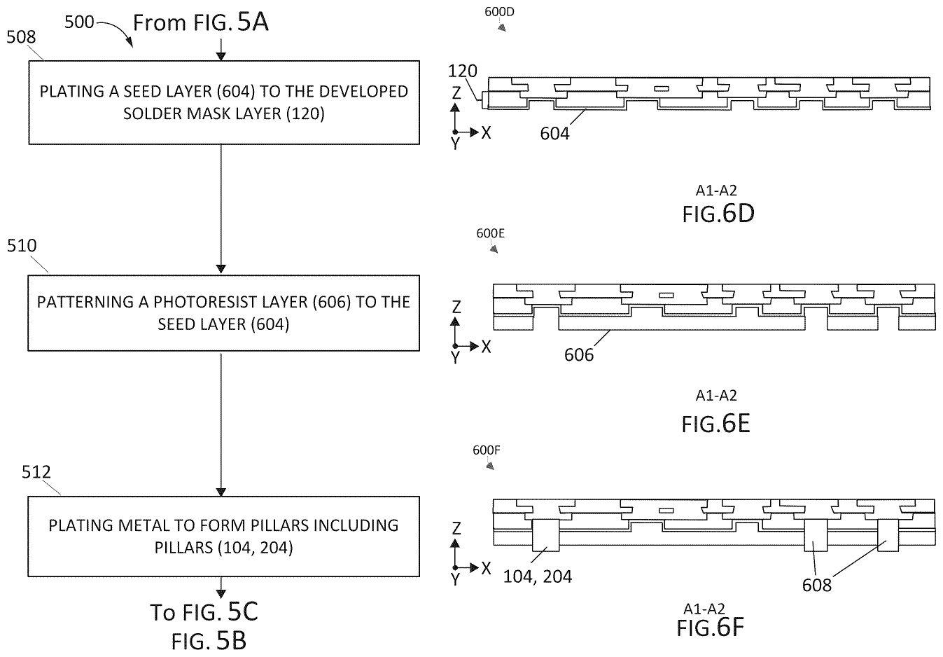

FIG. 3A is a side view of another exemplary 3DIC package 300 that includes a package interconnect 302 including a pillar 204 having a first sidewall 210 suitable for coupling solder to improve conductivity and structural integrity. Common elements between the IC package 300 in FIGS. 3A-3D and the IC packages 200, 300 in FIGS. 1A-1D and FIGS. 2A-2D are shown with common element numbers.

The package interconnect 302 extends in a vertical direction (Z-axis direction). The bottom surface 132 of the pillar 204 includes a metal surface finish 304. The metal surface finish 304 may be electroless nickel immersion gold (ENIG), a combination of electroless nickel, electroless palladium immersion gold (ENEPIG), or direct immersion gold (DIG).

FIG. 3B is a close-up view of the package interconnect 302 in FIG. 3A.

FIG. 3C is a view in the Z-axis direction of the bottom of the 3DIC package 300 of FIG. 3A illustrating the bottom surfaces of package interconnects including the package interconnect 302 in FIG. 3A;

FIG. 3D is a view of an electronic device 305 including the 3DIC package 300 in FIG. 3A assembled with the PCB 224 illustrating the coupling of a solder joint 306 to the first sidewall 210 of the pillar 204.

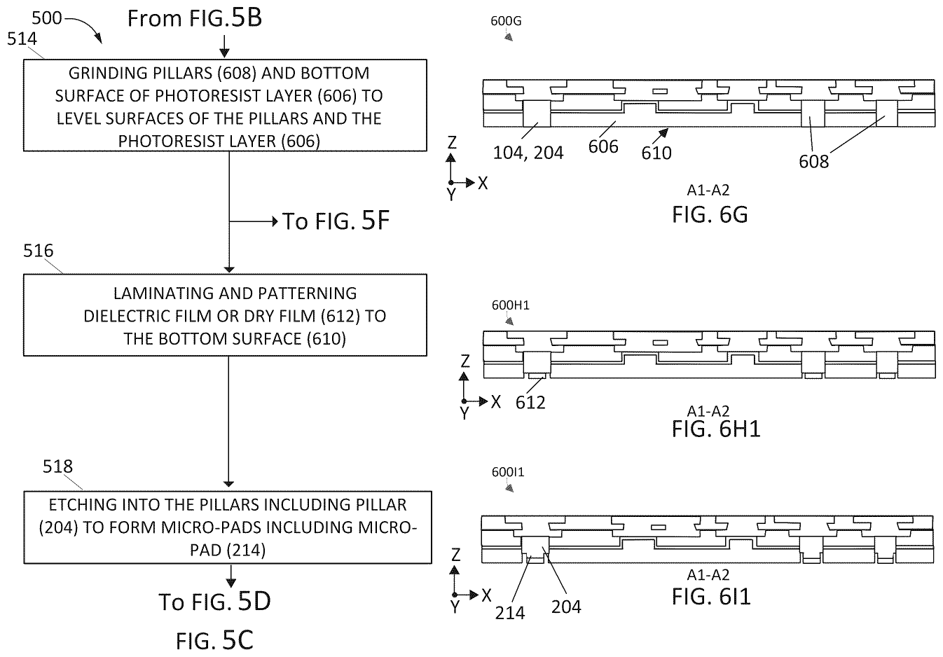

An electronic device including an IC package, such as the 3DIC packages 100, 200, and 300, which includes a package interconnect including a pillar and a solder cap coupled to a bottom surface of the pillar to reduce the height of the IC package including, but not limited to, the package interconnects in FIGS. 1A-1D, 2A-2D and 3A-3D can be fabricated by different fabrication processes. FIG. 4 is a flowchart illustrating an exemplary fabrication process of fabricating an electronic device including a package interconnect, wherein the package interconnect includes a pillar having a sidewall suitable for coupling solder to improve conductivity and structural integrity, the package interconnect, including, but not limited to, the package interconnect(s) in FIGS. 1A-1D, 2A-2D, and 3A-3D.

In this regard, a first exemplary step in the fabrication process 400 of FIG. 4 can include forming an IC package 200 (block 402). Forming the IC package 100, 200, 300 of the fabrication process 400 can include forming a substrate 106 extending in a horizontal direction, the substrate 106 comprising an outer metallization layer 110F having a metal pad 122 (block 404). A next step in forming the IC package 100, 200, 300 of the fabrication process 400 can include forming a package mold layer 124 extending in the horizontal direction and adjacent to the outer metallization layer 110F (block 406). Forming the package mold layer 124 of the fabrication process 400 can include forming a circular aperture 126, 206, the circular aperture 126, 206 having an aperture sidewall 128, 208 and an aperture diameter 136, 216 (block 408). A next step in forming the IC package 100, 200, 300 of the fabrication process 400 can include forming a package interconnect 102, 202, 302 extending in a vertical direction (block 410). Forming the package interconnect 102, 202, 302 of the fabrication process 400 can include forming a pillar 104, 204 extending in the vertical direction from the metal pad 122 and through the circular aperture 126, 206 (block 412). A next step of forming the package interconnect 102, 202, 302 of the fabrication process 400 can include forming a first sidewall 130, 210 having a first diameter 138, 218, the first diameter 138, 218 being less than the aperture diameter 136, 216 (block 414). A next step of forming the package interconnect 102, 202, 302 of the fabrication process 400 can include forming a second sidewall 134, 212 directly adjacent to the package mold layer 124 (block 416).

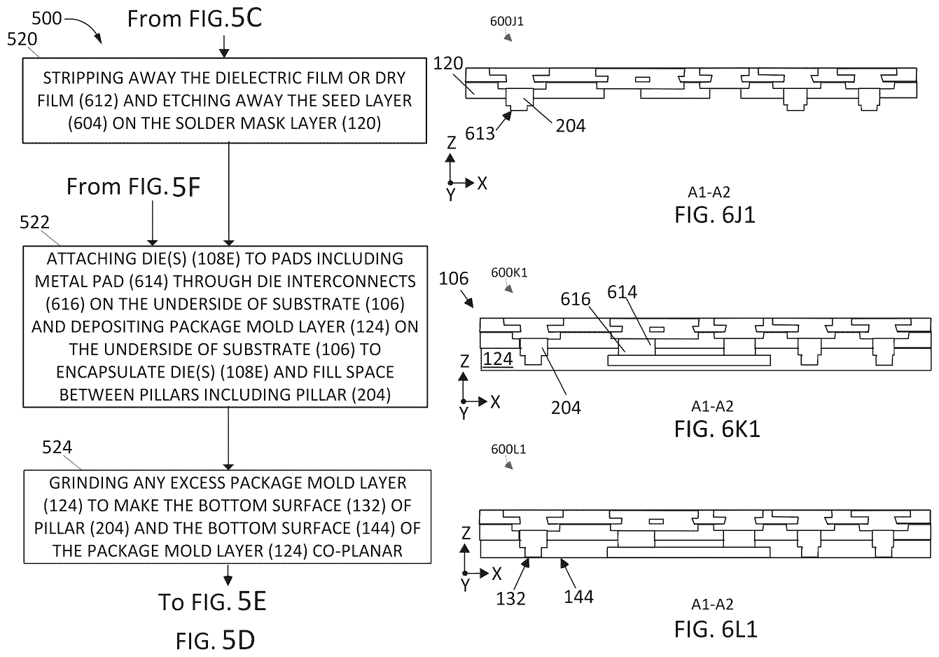

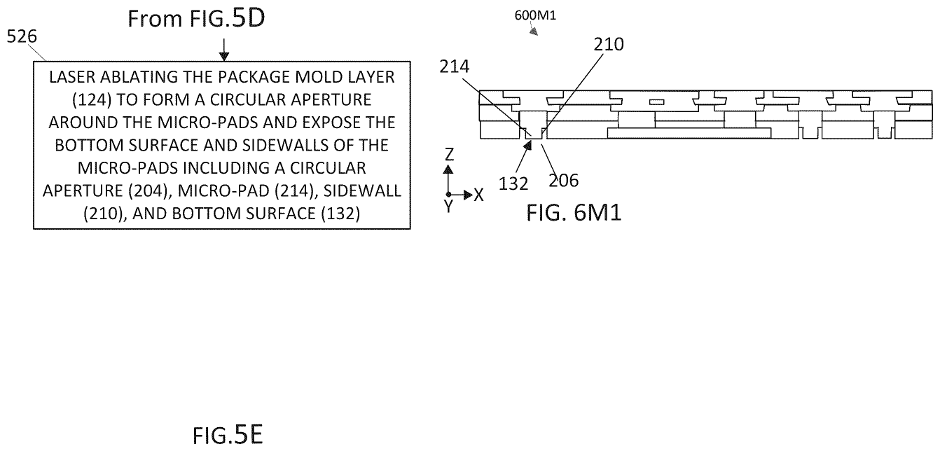

Other fabrication processes can also be employed to fabricate an electronic device including an IC package such as the 3DIC packages described in FIGS. 1A-1D, 2A-2D, and 3A-3D, wherein the 3DIC package includes a package interconnect, the package interconnect, including, but not limited to, the package interconnect(s) in FIGS. 1A-1D, 2A-2D, and 3A-3D. In this regard, FIGS. 5A-5F is a flowchart illustrating another exemplary fabrication process of fabricating a package interconnect such as the package interconnects described in FIGS. 1A-1D, 2A-2D and 3A-3D, wherein the package interconnect includes a pillar having a sidewall suitable for coupling solder to improve conductivity and structural integrity, the package interconnect, including, but not limited to, the package interconnect(s) in FIGS. 1A-1D, 2A-2D, and 3A-3D. FIGS. 6A-6I2 are exemplary fabrication stages during fabrication of the package interconnect according to the fabrication process in FIGS. 5A-5F.

In this regard, as shown in fabrication stage 600A in FIG. 6A, an exemplary step in the fabrication process 500 is plating outer interconnects 602 such as the metal pads 122 to the substrate 106 (block 502 in FIG. 5A). The plating process in block 502 may include depositing a copper (Cu) seed layer, applying a photo resist layer, exposing the photo resist layer to form an outline for the outer interconnects 602, plating metal (e.g., Cu) to form the outer interconnects 602 including the metal pad 122, and etching the remaining Cu seed layer. For simplicity, the fabrication process 500 will be described beginning at stage 600B from cut lines A1-A2 in FIG. 6A descending in the negative Z-axis direction in stage 600A. As shown at fabrication stage 600B in FIG. 6B, a next step in the fabrication process 500 can include laminating a solder mask layer 120 to the bottom surface of the substrate 106 (block 504 in FIG. 5A). As shown at fabrication stage 600C in FIG. 6C, a next step in the fabrication process 500 can include patterning the solder mask layer 120 to determine subsequent access to the outer interconnects 602 (block 506 in FIG. 5A). The patterning process in block 506 may include exposing the solder mask layer 120 to ultraviolet rays through a mask, developing the remaining solder mask layer 120, and desmearing the surfaces of the solder mask layer 120 and the outer interconnects 602 to roughen the respective surfaces for subsequent plating of a seed layer. As shown at fabrication stage 600D in FIG. 6D, a next step in the fabrication process 500 can include plating a seed layer 604 (e.g., Cu) to the developed solder mask layer 120 (block 508 in FIG. 5B). As shown at fabrication stage 600E in FIG. 6E, a next step in the fabrication process 500 can include patterning a photoresist layer 606 to the seed layer 604 (block 510 in FIG. 5B). The patterning process in block 510 may include laminating the photoresist layer 606 to the seed layer 604, exposing the photoresist layer 606 with ultraviolet rays through a mask, and developing the remaining photoresist layer 606. As shown at fabrication stage 600F in FIG. 6F, a next step in the fabrication process 500 can include plating metal (e.g., Cu) to form pillars 608 including the pillars 104, 204 (block 512 in FIG. 5B).

As shown at fabrication stage 600G in FIG. 6G, a next step in the fabrication process 500 can include grinding the pillars 608 including the pillars 104, 204 and a bottom surface 610 of the photoresist layer 606 to level the surfaces of the pillars 608 and the photoresist layer 606 (block 514 in FIG. 5C).

After stage 600G, two alternative paths for fabricating the package interconnects 202, 302 will be discussed. The first path that will be described includes blocks 516-526 in FIG. 5. The second path that will be described includes blocks 528-530 and 522-526.

As shown at fabrication stage 600H1 in FIG. 6H1, a next step in the fabrication process 500 can include laminating and patterning dielectric film or dry film 612 to the bottom surface 610 (block 516 in FIG. 5C). As shown at fabrication stage 600I1 in FIG. 6I1, a next step in the fabrication process 500 can include etching into the pillars including pillar 204 to form micro-pads including micro-pad 214 (block 518 in FIG. 5C).

As shown at fabrication stage 600J1 in FIG. 6J1, a next step in the fabrication process 500 can include stripping away the dielectric film or dry film 612 and etching away the seed layer 604 on the solder mask layer 120 (block 520 in FIG. 5D). At this point in fabrication process 500, the fabrication process 500 may optionally include applying a metal surface finish to the bottom surface 613 of pillar 204. Known processes for applying the metal surface finish to the bottom surface 613 include electroless nickel immersion gold (ENIG), a combination of electroless nickel, electroless palladium immersion gold (ENEPIG), or direct immersion gold (DIG) processes. As shown at fabrication stage 600K1 in FIG. 6K1, a next step in the fabrication process 500 can include attaching a die(s) 108E to pads including a metal pad 614 through die interconnects 616 on the underside of the substrate 106 and depositing the package mold layer 124 on the underside of the substrate 106 to encapsulate the die(s) 108E and fill space between the pillars including pillar 204 (block 522 in FIG. 5D). As shown at fabrication stage 600L1 in FIG. 6L1, a next step in the fabrication process 500 can include grinding any excess package mold layer 124 to make the bottom surface 132 of the pillar 204 and the bottom surface 144 of the package mold layer 124 co-planar (block 524 in FIG. 5D). As shown at fabrication stage 600M1 in FIG. 6M1, a next step in the fabrication process 500 can include laser ablating the package mold layer 124 to form a circular aperture around the micro-pads and expose the bottom surface and sidewalls of the micro-pads including a circular aperture 204, micro-pad 214, sidewall 210, and bottom surface 132 (block 526 in FIG. 5E).

Returning to block 514, the second path for fabricating the package interconnect 202, 302 will be discussed. As shown at fabrication stage 600H2 in FIG. 6H1, a next step in the fabrication process 500 can include laminating and patterning dielectric film or dry film 612 to the bottom surface 610 and copper (Cu) plating micro-pads including micro-pad 214 (block 528 in FIG. 5F). As shown at fabrication stage 600I2 in FIG. 6I2, a next step in the fabrication process 500 can include stripping the dielectric film or dry film 612 and etching away the seed layer 604 from the solder mask 120 (block 530 in FIG. 5F). At this point in fabrication process 500, the fabrication process 500 may optionally include applying a metal surface finish to the bottom surface 613 of pillar 204. Known processes for applying the metal surface finish to the bottom surface 613 include electroless nickel immersion gold (ENIG), a combination of electroless nickel, electroless palladium immersion gold (ENEPIG), or direct immersion gold (DIG) processes. To assemble the die(s) 108E, the next step in the fabrication process 500 for this second path can include blocks 522-526 as described above.

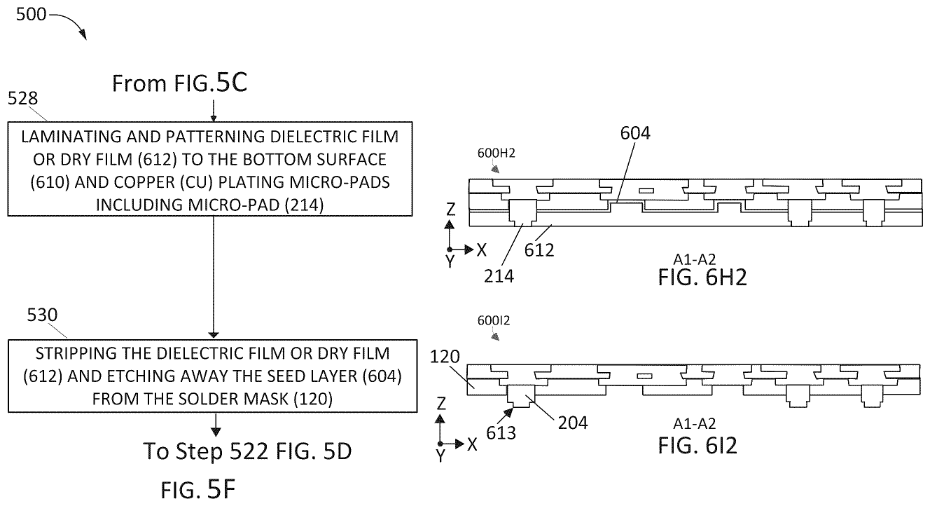

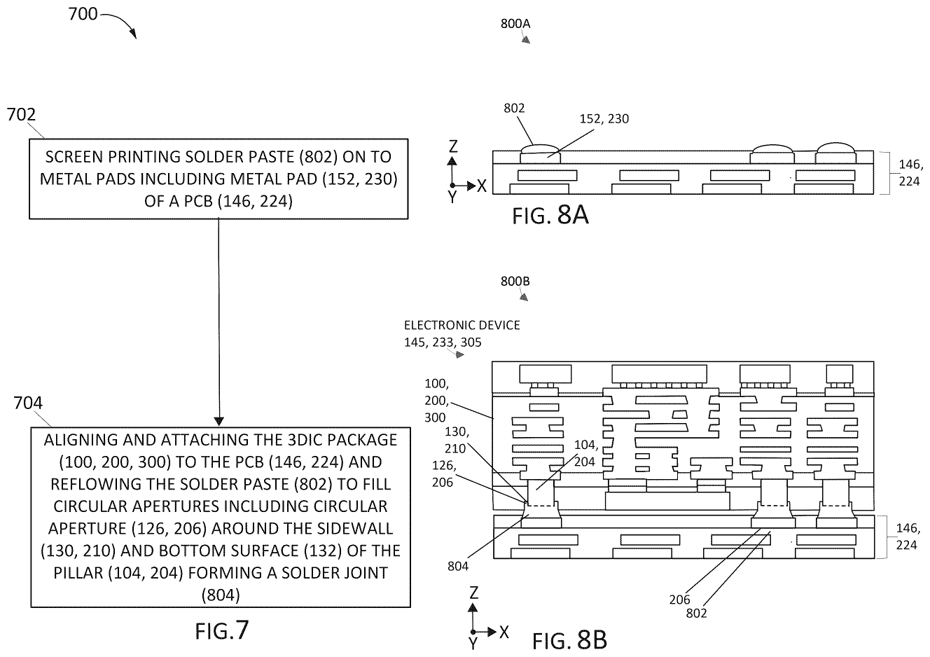

FIG. 7 is a flowchart illustrating an exemplary assembly process 700 of assembling an electronic device 145, 233, 305 such as the electronic device having a 3DIC package 100, 200, 300 coupled to a PCB 146, 224 in FIGS. 1D, 2D, and 3D and utilizing the 3DIC package fabricated according to the fabrication process in FIGS. 5A-5F, wherein the 3DIC package employs a package interconnect including a pillar having a sidewall suitable for coupling solder to improve conductivity and structural integrity, the package interconnect, including, but not limited to, the package interconnect(s) in FIGS. 1A-1D, 2A-2D, and 3A-3D. FIGS. 8A-8B are exemplary assembly stages during assembly of the electronic device according to the assembly process 700 in FIG. 7.

In this regard, as shown in assembly stage 800A in FIG. 8A, an exemplary step in the assembly process 700 is screen printing solder paste 802 on to metal pads including metal pad 152, 230 of a PCB 146, 224 (block 702 in FIG. 7). As shown at assembly stage 800B in FIG. 8B, a next step in the assembly process 700 can include aligning and attaching the 3DIC package 100, 200, 300 to the PCB 146, 224 and reflowing the solder paste 802 to fill circular apertures including circular aperture 126, 206 around the sidewall 130, 210 and bottom surface 132 of the pillar 104, 204 forming a solder joint 804 (block 704 in FIG. 7).

Electronic devices that include an IC package, wherein the 3DIC package is fabricated according to the fabrication process in FIGS. 4 and 5A-5F, wherein the 3DIC package employs a package interconnect including a pillar having a sidewall suitable for coupling solder to improve conductivity and structural integrity, including, but not limited to, the package interconnects in FIGS. 1A-1D, 2A-2D and 3A-3D and according to the exemplary processes in FIGS. 4 and 5A-5F, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

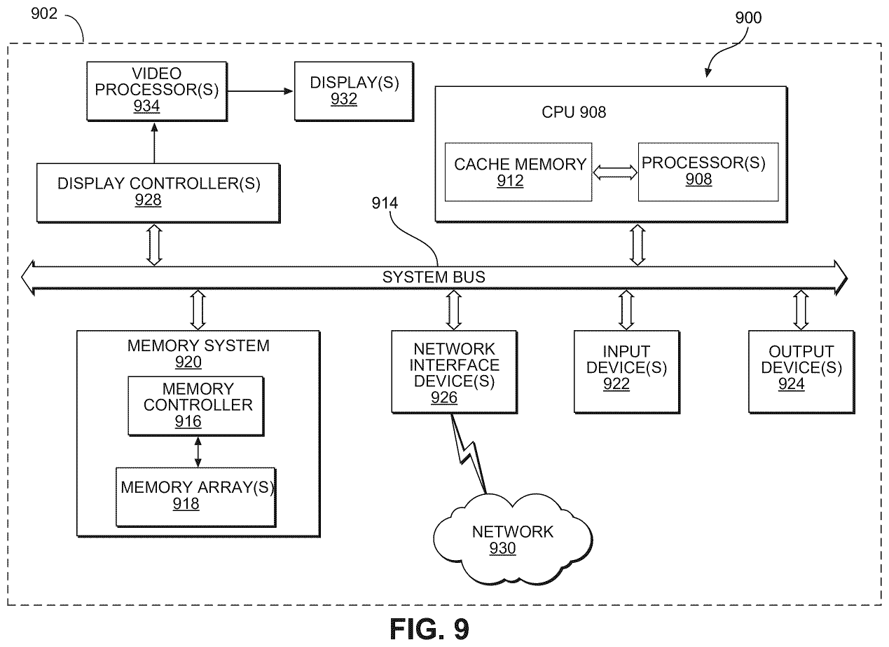

In this regard, FIG. 9 is a block diagram of an exemplary processor-based system 900 that can include components such as an electronic device, wherein the electronic device includes a 3DIC package fabricated according to the fabrication process in FIGS. 4 and 5A-5F, wherein the 3DIC package employs a package interconnect including a pillar having a sidewall suitable for coupling solder to improve conductivity and structural integrity, the package interconnect, including, but not limited to, the package interconnect(s) in FIGS. 1A-1D, 2A-2D, and 3A-3D, and according to any exemplary aspects disclosed herein. In this example, the processor-based system 900 may be assembled into one electronic device 902 including a 3DIC package(s) such as the IC packages 100, 200, 300 employing a package interconnect. The processor-based system 900 includes a central processing unit (CPU) 908 that includes one or more processors 910, which may also be referred to as CPU cores or processor cores. The CPU 908 may have cache memory 912 coupled to the CPU 908 for rapid access to temporarily stored data. The CPU 908 is coupled to a system bus 914 and can intercouple client and server devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other client and server devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. Each of the memory system(s) 920, the one or more input devices 922, the one or more output devices 924, the one or more network interface devices 926, and the one or more display controllers 928 can be provided in the same or different electronic devices. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processor(s) 934, which process the information to be displayed into a format suitable for the display(s) 932. The display controller(s) 928 and video processor(s) 934 can be included as ICs in the same or different electronic devices, and in the same or different electronic devices containing the CPU 908, as an example. The display(s) 932 can include any type of display, including, but not limited to, a cathode ray tube (CRT), a liquid crystal display (LCD), a plasma display, a light emitting diode (LED) display, etc.

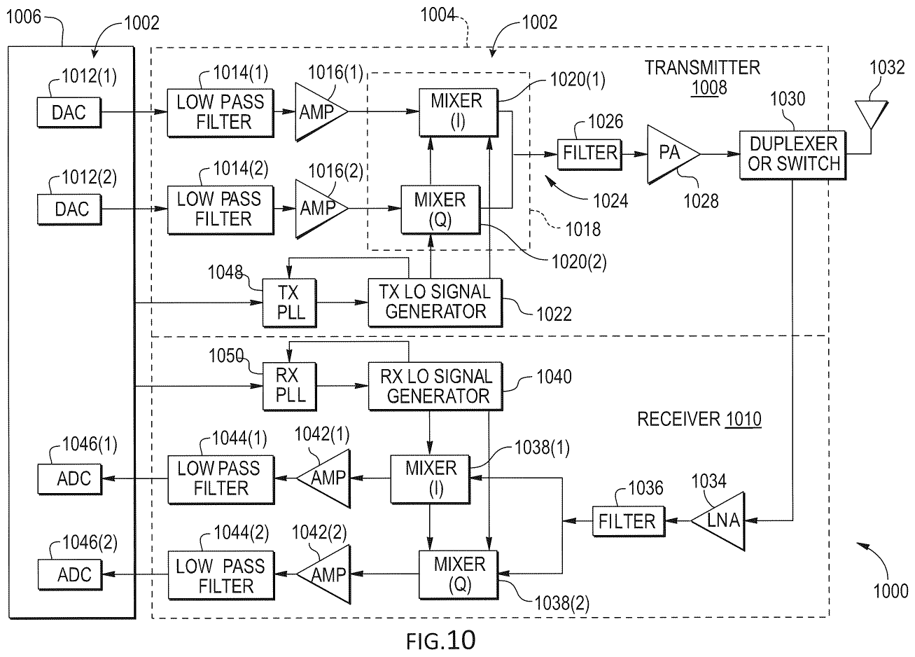

FIG. 10 is a block diagram of an exemplary wireless communications device 1000 that includes radio-frequency (RF) components formed from one or more electronic devices, wherein the electronic device includes a 3DIC package 1002 fabricated according to the fabrication process in FIGS. 4 and 5A-5E, wherein the 3DIC package 1002 employs a package interconnect including a pillar and a solder cap coupled to a bottom surface of the pillar to reduce the height of the 3DIC package including, but not limited to, the package interconnect(s) in FIGS. 2 and 3, and according to any exemplary aspects disclosed herein. The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals (e.g., I and Q output currents) for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. An electronic device, comprising:

an integrated circuit (IC) package, comprising:
a substrate extending in a horizontal direction, the substrate comprising an outer metallization layer having a metal pad;
a package mold layer extending in the horizontal direction and adjacent to the outer metallization layer, the package mold layer having a circular aperture, the circular aperture having an aperture sidewall and an aperture diameter; and
a package interconnect extending in a vertical direction, comprising:
   a pillar extending in the vertical direction from the metal pad and through the circular aperture, the pillar comprising:
      a first sidewall having a first diameter, the first diameter being less than the aperture diameter; and
      a second sidewall directly adjacent to the package mold layer.

2. The electronic device of clause 1, wherein:

the package mold layer comprises a first bottom surface; and

the pillar comprises a second bottom surface, the second bottom surface being co-planar with the first bottom surface of the package mold layer.

3. The electronic device of clause 2, wherein:

the second sidewall has a second diameter; and

the pillar comprises:
a micro-pad, comprising:
   the first sidewall, the first diameter being less than the second diameter.

4. The electronic device of clause 3, wherein a ratio between the second diameter and the first diameter is around 0.80.

5. The electronic device of any of clauses 1-3, wherein the second bottom surface of the pillar comprises:

a metal surface finish.

6. The electronic device of clause 5, wherein the metal surface finish is selected from the group comprising: electroless nickel immersion gold (ENIG), electroless nickel electroless palladium immersion gold (ENEPIG), and direct immersion gold (DIG).

7. The electronic device of any of clauses 1-6, wherein a ratio between the first diameter and the aperture diameter is around 0.80.

8. The electronic device of any of clauses 1-7, further comprising:

a solder mask layer between the package mold layer and the outer metallization layer, the pillar extending through the solder mask layer and the package mold layer.

9. The electronic device of any of clauses 2-8, further comprising:

a printed circuit board (PCB), comprising:
a second metal pad; and
solder coupled to the second metal pad and coupled to the second bottom surface and extending along the second sidewall within the circular aperture.

10. The electronic device of any of clauses 1-9 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

11. A method of fabricating an electronic device, comprising:

forming an integrated circuit (IC) package, comprising:
forming a substrate extending in a horizontal direction, the substrate comprising an outer metallization layer having a metal pad;
forming a package mold layer extending in the horizontal direction and adjacent to the outer metallization layer, comprising:
   forming a circular aperture, the circular aperture having an aperture sidewall and an aperture diameter; and
forming a package interconnect extending in a vertical direction, comprising:
   forming a pillar extending in the vertical direction from the metal pad and through the circular aperture, the pillar comprising:
      forming a first sidewall having a first diameter, the first diameter being less than the aperture diameter; and
      forming a second sidewall directly adjacent to the package mold layer.

12. The method of clause 11, wherein:

the package mold layer comprises a first bottom surface; and

the pillar comprises a second bottom surface, the second bottom surface being co-planar with the first bottom surface of the package mold layer.

13. The method of clause 12, wherein:

the second sidewall has a second diameter; and

the pillar comprises:
a micro-pad, comprising:
   the first sidewall, the first diameter being less than the second diameter.

14. The method of any of clauses 11-13, wherein forming the circular aperture comprises:

laser ablating the package mold layer.

15. The method of any of clauses 11-14, wherein forming the circular aperture comprises:

laser ablating a bottom surface of the pillar.

16. The method of any of clauses 13-15, wherein the second bottom surface of the pillar comprises:

a metal surface finish.

17. The method of clause 16, wherein the metal surface finish is selected from the group comprising: electroless nickel immersion gold (ENIG), electroless nickel electroless palladium immersion gold (ENEPIG), and direct immersion gold (DIG).

18. The method of any of clauses 11-17, wherein a ratio between the first diameter and the aperture diameter is around 0.80.

19. The method of any of clauses 11-18, further comprising:

forming a solder mask layer between the package mold layer and the outer metallization layer, the pillar extending through the solder mask layer and the package mold layer.

20. The method of any of clauses 12-19, further comprising:

assembling the electronic device, comprising:
aligning a second metal pad of a printed circuit board (PCB) with the second bottom surface;
applying solder to the second metal pad;
coupling the second bottom surface to the second metal pad; and
reflowing the electronic device to form a solder joint extending along the second sidewall within the circular aperture.

What is claimed is:

1. An electronic device, comprising:
an integrated circuit (IC) package, comprising:
a substrate extending in a horizontal direction, the substrate comprising an outer metallization layer having a metal pad;
a package mold layer extending in the horizontal direction and adjacent to the outer metallization layer, the package mold layer having a circular aperture, the circular aperture having an aperture sidewall and an aperture diameter; and
a package interconnect extending in a vertical direction, comprising:
a pillar extending in the vertical direction from the metal pad and through the circular aperture, the pillar comprising:
a first sidewall having a first diameter, the first diameter being less than the aperture diameter; and
a second sidewall directly adjacent to the package mold layer.

2. The electronic device of claim 1, wherein:
the package mold layer comprises a first bottom surface; and
the pillar comprises a second bottom surface, the second bottom surface being co-planar with the first bottom surface of the package mold layer.

3. The electronic device of claim 2, wherein:
the second sidewall has a second diameter; and
the pillar comprises:
a micro-pad, comprising:
the first sidewall, the first diameter being less than the second diameter.

4. The electronic device of claim 3, wherein a ratio between the second diameter and the first diameter is around 0.80.

5. The electronic device of claim 3, wherein the second bottom surface of the pillar comprises:
a metal surface finish.

6. The electronic device of claim 5, wherein the metal surface finish is selected from the group comprising: electroless nickel immersion gold (ENIG), electroless nickel electroless palladium immersion gold (ENEPIG), and direct immersion gold (DIG).

7. The electronic device of claim 1, wherein a ratio between the first diameter and the aperture diameter is around 0.80.

8. The electronic device of claim 1, further comprising:
a solder mask layer between the package mold layer and the outer metallization layer, the pillar extending through the solder mask layer and the package mold layer.

9. The electronic device of claim 2, further comprising:
a printed circuit board (PCB), comprising:
a second metal pad; and
solder coupled to the second metal pad and coupled to the second bottom surface and extending along the second sidewall within the circular aperture.

10. The electronic device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

11. A method of fabricating an electronic device, comprising:
forming an integrated circuit (IC) package, comprising:
forming a substrate extending in a horizontal direction, the substrate comprising an outer metallization layer having a metal pad;
forming a package mold layer extending in the horizontal direction and adjacent to the outer metallization layer, comprising:
forming a circular aperture, the circular aperture having an aperture sidewall and an aperture diameter; and
forming a package interconnect extending in a vertical direction, comprising:
forming a pillar extending in the vertical direction from the metal pad and through the circular aperture, the pillar comprising:
forming a first sidewall having a first diameter, the first diameter being less than the aperture diameter; and
forming a second sidewall directly adjacent to the package mold layer.

12. The method of claim 11, wherein:
the package mold layer comprises a first bottom surface; and
the pillar comprises a second bottom surface, the second bottom surface being co-planar with the first bottom surface of the package mold layer.

13. The method of claim 12, wherein:
the second sidewall has a second diameter; and
the pillar comprises:
a micro-pad, comprising:
the first sidewall, the first diameter being less than the second diameter.

14. The method of claim 11, wherein forming the circular aperture comprises:
laser ablating the package mold layer.

15. The method of claim 11, wherein forming the circular aperture comprises:
laser ablating a bottom surface of the pillar.

16. The method of claim 13, wherein the second bottom surface of the pillar comprises:
a metal surface finish.

17. The method of claim 16, wherein the metal surface finish is selected from the group comprising: electroless nickel immersion gold (ENIG), electroless nickel electroless palladium immersion gold (ENEPIG), and direct immersion gold (DIG).

18. The method of claim 11, wherein a ratio between the first diameter and the aperture diameter is around 0.80.

19. The method of claim 11, further comprising:
forming a solder mask layer between the package mold layer and the outer metallization layer, the pillar extending through the solder mask layer and the package mold layer.

20. The method of claim 12, further comprising:
assembling the electronic device, comprising:
aligning a second metal pad of a printed circuit board (PCB) with the second bottom surface;
applying solder to the second metal pad;
coupling the second bottom surface to the second metal pad; and
reflowing the electronic device to form a solder joint extending along the second sidewall within the circular aperture.
